(19) United States
(12) Patent Application Publication
(10) Pub. No.: US 2015/0013594 A1
(43) Pub. Date: Jan. 15, 2015

(54) VAPOR PHASE GROWTH APPARATUS AND VAPOR PHASE GROWTH METHOD

(71) Applicant: NuFlare Technology, Inc., Yokohama (JP)

(72) Inventors: Takumi YAMADA, Kanagawa (JP); Yuusuke SATO, Tokyo (JP)

(73) Assignee: NuFlare Technology, Inc., Yokohama (JP)

(21) Appl. No.: 14/322,270

(22) Filed: Jul. 2, 2014

(30) Foreign Application Priority Data
Jul. 8, 2013 (JP) 2013-142617

(51) Int. Cl. C30B 25/14; C30B 25/16

(52) U.S. Cl. CPC C30B 25/14; C30B 25/16; C30B 29/406
USPC 117/102; 117/104; 118/715

(57) ABSTRACT

A vapor phase growth apparatus of an embodiment includes: a reaction chamber; a first gas supply path configured to supply a first process gas including organic metal and a carrier gas into the reaction chamber; a second gas supply path configured to supply a second process gas including ammonia into the reaction chamber; a first carrier gas supply path configured to supply a first carrier gas of a hydrogen or inert gas into the first gas supply path while being connected to the first gas supply path and including a first mass flow controller; and a second carrier gas supply path configured to supply a second carrier gas of a hydrogen or inert gas different from the first carrier gas into the first gas supply path while being connected to the first gas supply path and including a second mass flow controller.

### CROSS-REFERENCE TO RELATED APPLICATION

This application is based upon and claims the benefit of priority from Japanese Patent Application No. 2013-142617, filed on Jul. 8, 2013, the entire contents of which are incorporated herein by reference.

### FIELD OF THE INVENTION

Embodiments described herein relate generally to a vapor phase growth apparatus and a vapor phase growth method of forming a film by supplying a gas thereto.

### BACKGROUND OF THE INVENTION

As a method of forming a high-quality semiconductor film, there is known an epitaxial growth technique of growing a single-crystal film on a substrate such as a wafer by the vapor phase growth. In a vapor phase growth apparatus that uses the epitaxial growth technique, a wafer is placed on a support portion inside a reaction chamber that is maintained in a normal pressure state or a reduced pressure state. Then, a process gas such as a source gas used as a raw material for forming a film is supplied from, for example, a shower head at the upper portion of the reaction chamber to a wafer surface while the wafer is heated. Thus, a thermal reaction of the source gas occurs on the surface of the wafer, and hence an epitaxial single-crystal film is formed on the surface of the wafer.

In recent years, a semiconductor device using GaN (gallium nitride) has been gaining attention as a material of a light emitting device or a power device. As the epitaxial growth technique that forms a GaN-based semiconductor, a metal organic chemical vapor deposition (MOCVD) is known. In the metal organic chemical vapor deposition, for example, organic metal such as trimethylgallium (TMG), trimethylindium (TMI), and trimethylaluminum (TMA) or ammonia (NH₃) is used as the source gas. Also, there is a case in which hydrogen (H₂) is used as a separation gas in order to suppress the reaction in the source gas.

In order to uniformly form a film on the surface of the wafer in the epitaxial growth technique, especially in MOCVD, it is important to appropriately mix the source gas, the separation gas, or the like and to supply the resultant gas to the surface of the wafer in a uniformly rectified state. JP-A 2010-219116 discloses the configuration that the mixed gas is used as the separation gas.

### SUMMARY OF THE INVENTION

According to an aspect of the disclosure, there is provided a vapor phase growth apparatus including: a reaction chamber; a first gas supply path connected to the reaction chamber, the first gas supply path configured to supply a first process gas including organic metal and a carrier gas into the reaction chamber; a second gas supply path connected to the reaction chamber, the second gas supply path configured to supply a second process gas including ammonia into the reaction chamber; a first carrier gas supply path connected to the first gas supply path, the first carrier gas supply path having a first mass flow controller, the first carrier gas supply path configured to supply a first carrier gas of a hydrogen or inert gas into the first gas supply path; and a second carrier gas supply path connected to the first gas supply path, the second carrier gas supply path having a second mass flow controller, the second carrier gas supply path configured to supply a second carrier gas of a hydrogen or inert gas different from the first carrier gas into the first gas supply path.

According to an aspect of the disclosure, there is provided a vapor phase growth method including: carrying in a substrate into a reaction chamber; heating the substrate; and forming a semiconductor film on a substrate surface by supplying a first process gas including organic metal and a first mixed gas obtained by mixing a first carrier gas of a hydrogen or inert gas with a second carrier gas of a hydrogen or inert gas different from the first carrier gas and a second process gas including ammonia into the reaction chamber.

In the vapor phase growth method of the above-described aspect, a second mixed gas obtained by mixing a first compensation gas of a hydrogen or inert gas with a second compensation gas of a hydrogen or inert gas different from the first compensation gas may be supplied into the reaction chamber before the supply of the second process gas into the reaction chamber, and a semiconductor film may be formed on the substrate surface by switching the supply gas from the second mixed gas to the second process gas.

### BRIEF DESCRIPTION OF THE DRAWINGS

FIG. 1 is a configuration diagram of a vapor phase growth apparatus of a first embodiment;

FIG. 2 is a schematic cross-sectional view illustrating a main part of the vapor phase growth apparatus of the first embodiment;

FIG. 3 is a schematic top view illustrating a shower plate of the first embodiment;

FIG. 4 is a cross-sectional view taken along the line AA of the shower plate of FIG. 3;

FIGS. 5A, 5B, and 5C are cross-sectional views taken along the lines BB, CC, and DD of the shower plate of FIG. 3;

FIG. 6 is a configuration diagram of a vapor phase growth apparatus of a second embodiment; and

FIG. 7 is a configuration diagram of a vapor phase growth apparatus of a third embodiment.

### DETAILED DESCRIPTION OF THE EMBODIMENTS

Hereinafter, embodiments will be described with reference to the drawings.

Furthermore, in the specification, the gravity direction in the state where a vapor phase growth apparatus is provided so as to form a film is defined as the “down”, and the opposite direction is defined as the “up”. Accordingly, the “lower portion” indicates the position of the gravity direction with respect to the reference, and the “downside” indicates the gravity direction with respect to the reference. Then, the “upper portion” indicates the position in the direction opposite to the gravity direction with respect to the reference, and the “upside” indicates the direction opposite to the gravity direction with respect to the reference. Further, the “longitudinal direction” indicates the gravity direction.

Further, in the specification, the “horizontal plane” indicates a plane perpendicular to the gravity direction.

Further, in the specification, the “process gas” generally indicates a gas used to form a film on the substrate, and corresponds to, for example, a concept including a source gas, a carrier gas, a separation gas, a compensation gas, and the like.

Further, in the specification, the “compensation gas” indicates a process gas that is supplied to the reaction chamber along with the source gas by the same supply path before the source gas is supplied to the reaction chamber and does not include the source gas. When the compensation gas is changed to the source gas directly before the film formation process, a change in environment such as a pressure change and a temperature change inside the reaction chamber is suppressed as much as possible, and hence the film formation process is stably performed on the substrate.

Further, in the specification, the “separation gas” indicates a process gas which is introduced into the reaction chamber of the vapor phase growth apparatus, and generally indicates a gas which separates the process gases of plural raw material gases. For example, the separation gas corresponds to the concept including a process gas, a so-called sub-flow gas, and the like for separating a reaction gas and a ceiling portion of a horizontal vapor phase growth apparatus from each other in order to suppress the sedimentation of a film on the ceiling portion due to the reaction with a raw material gas.

Further, in the specification, the “nitrogen gas” is included in the “inert gas”.

### First Embodiment

A vapor phase growth apparatus of the embodiment includes: a reaction chamber; a first gas supply path configured to supply a first process gas including organic metal and a carrier gas into the reaction chamber; a second gas supply path configured to supply a second process gas including ammonia into the reaction chamber; a first carrier gas supply path configured to supply a first carrier gas of a hydrogen or inert gas into the first gas supply path while being connected to the first gas supply path and including a first mass flow controller; and a second carrier gas supply path configured to supply a second carrier gas of a hydrogen or inert gas different from the first carrier gas into the first gas supply path while being connected to the first gas supply path and including a second mass flow controller.

Further, a vapor phase growth method of the embodiment includes: carrying in a substrate into a reaction chamber; heating the substrate; and forming a semiconductor film on a substrate surface by supplying a first process gas including organic metal and a first mixed gas obtained by mixing a first carrier gas of a hydrogen or inert gas with a second carrier gas of a hydrogen or inert gas different from the first carrier gas and a second process gas including ammonia into the reaction chamber. Further, a second mixed gas obtained by mixing a first compensation gas of a hydrogen or inert gas with a second compensation gas of a hydrogen or inert gas different from the first compensation gas is supplied into the reaction chamber before the supply of the second process gas into the reaction chamber, and a semiconductor film is formed on the substrate surface by switching the supply gas from the second mixed gas to the second process gas. Moreover, a third mixed gas obtained by mixing a first separation gas of a hydrogen or inert gas with a second separation gas of a hydrogen or inert gas different from the first separation gas is supplied into the reaction chamber along with the first process gas and the second process gas when the first process gas and the second process gas are supplied into the reaction chamber. In addition, the third mixed gas is ejected from a third gas ejection hole provided between a first gas ejection hole ejecting the first process gas into the reaction chamber and a second gas ejection hole ejecting the second process gas into the reaction chamber.

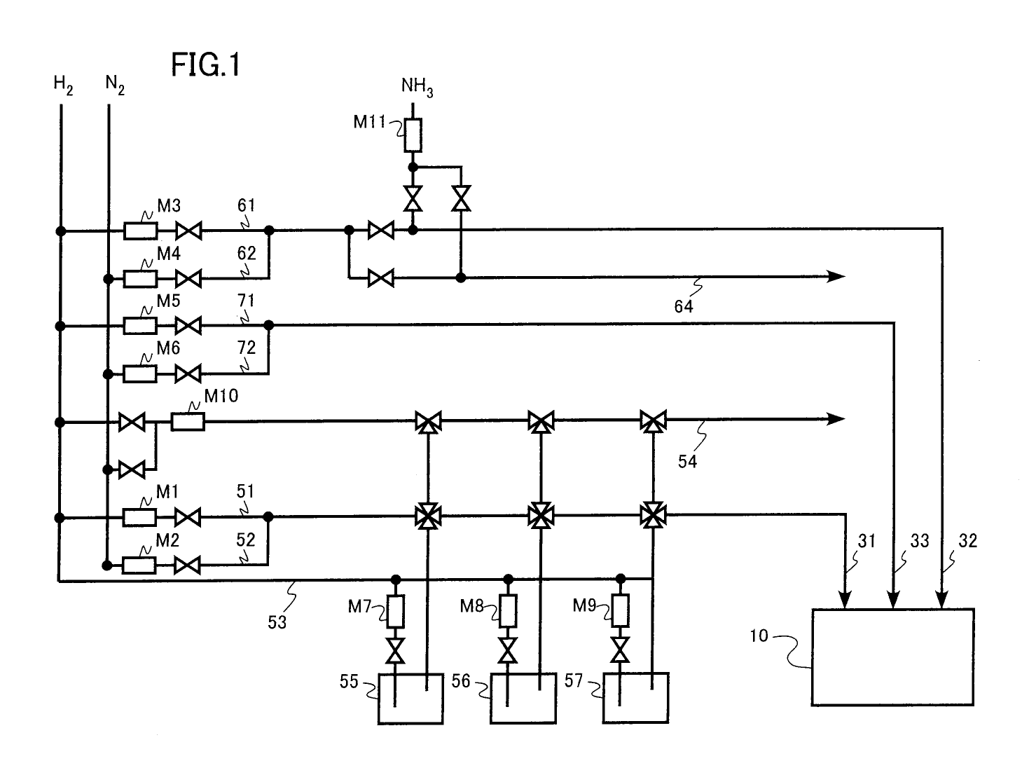

FIG. 1 is a configuration diagram of the vapor phase growth apparatus of the embodiment. The vapor phase growth apparatus of the embodiment is a vertical single wafer type epitaxial growth apparatus that uses MOCVD (metal organic chemical vapor deposition). Hereinafter, a case will be mainly described in which the epitaxial growth of GaN (gallium nitride) is performed.

The vapor phase growth apparatus includes a reaction chamber 10 in which a film is formed on a substrate such as a wafer. Then, the vapor phase growth apparatus includes a first gas supply path 31, a second gas supply path 32, and a third gas supply path 33 which supply process gases into the reaction chamber.

The first gas supply path 31 supplies a first process gas including a carrier gas and organic metal of a group-III element into the reaction chamber. The first process gas is a gas which includes a group-III element when the films of semiconductors of groups III to V are formed on the wafer.

The group-III element is, for example, gallium (Ga), Al (aluminum), In (indium), or the like. Further, the organic metal is trimethylgallium (TMG), trimethylaluminum (TMA), trimethylindium (TMI), or the like.

The second gas supply path 32 supplies a second process gas including ammonia (NH₃) into the reaction chamber. The second process gas is a source gas of nitrogen (N) and a group-V element when the films of semiconductors of groups III to V are formed on the wafer.

The vapor phase growth apparatus includes a mass flow controller M11 which controls the flow amount of ammonia introduced into the second gas supply path 32.

Further, the third gas supply path 33 is provided so as to supply a third process gas into the reaction chamber. The third process gas is a so-called separation gas, and is ejected between the first process gas and the second process gas when both gases are ejected into the reaction chamber 10. Accordingly, the reaction between the first process gas and the second process gas immediately after the ejection thereof is suppressed.

The vapor phase growth apparatus includes a first carrier gas supply path 51 which is connected to the first gas supply path 31 and a second carrier gas supply path 52 which is connected to the first gas supply path 31. The first carrier gas supply path 51 supplies a first carrier gas into the first gas supply path 31. The second carrier gas supply path 52 supplies a second carrier gas into the first gas supply path 31. The molecular weight of the first carrier gas is smaller than that of ammonia (NH₃), and the molecular weight of the second carrier gas is larger than that of ammonia (NH₃). For example, the first carrier gas is a hydrogen gas (H₂), and the second carrier gas is a nitrogen gas (N₂).

Then, the first carrier gas supply path 51 includes the mass flow controller M1 (a first mass flow controller) which controls the flow amount of the first carrier gas. Further, the second carrier gas supply path 52 includes a mass flow controller M2 (a second mass flow controller) which controls the flow amount of the second carrier gas.

Further, first to third organic metal storage containers 55, 56, and 57 which store organic metal are provided. The first organic metal storage container 55 stores, for example, TMG, the second organic metal storage container 56 stores, for example, TMA, and the third organic metal storage container 57 stores, for example, TMI.

Further, a third carrier gas supply path 53 is provided into which a carrier gas for bubbling the organic metal of the first to third organic metal storage containers 55, 56, and 57 is introduced. In addition, mass flow controllers M7, M8, and M9 are provided which control the flow amount of the carrier gas introduced into the first to third organic metal storage containers 55, 56, and 57. The carrier gas used for the bubbling is, for example, a hydrogen gas. In the case where the four-way valve is opened, the organic metal is supplied to the first gas supply path 31, and in the case where the four-way valve is closed, the organic metal is not supplied to the first gas supply path 31.

Further, a first gas discharge path 54 is provided. The first gas discharge path 54 is provided so as to discharge the first process gas to the downstream side of the apparatus when the vapor phase growth apparatus does not perform the film formation process. In the case where the three-way valve is opened, the organic metal is supplied to the first gas discharge path 54, and in the case where the three-way valve is closed, the organic metal is not supplied to the first gas discharge path 54.

The vapor phase growth apparatus includes a first compensation gas supply path 61 which is connected to the second gas supply path 32 and supplies a first compensation gas of a hydrogen or inert gas into the second gas supply path 32. Further, a second compensation gas supply path 62 is provided which is connected to the second gas supply path 32 and supplies a second compensation gas of a hydrogen or inert gas different from the first compensation gas to the second gas supply path 32.

The molecular weight of the first compensation gas is smaller than that of the ammonia (NH₃), and the molecular weight of the second compensation gas is larger than that of the ammonia (NH₃). For example, the first compensation gas is the hydrogen gas. Further, for example, the second compensation gas is the nitrogen gas.

Then, the first compensation gas supply path 61 includes a mass flow controller M3 (a third mass flow controller) which controls the flow amount of the first compensation gas. Further, the second compensation gas supply path 62 includes a mass flow controller M4 (a fourth mass flow controller) which controls the flow amount of the second compensation gas.

Further, a second gas discharge path 64 is provided.

The second gas discharge path 64 is provided so as to discharge the second process gas or the compensation gas to the downstream side of the apparatus.

The vapor phase growth apparatus includes a first separation gas supply path 71 which is connected to the third gas supply path 33 and a second separation gas supply path 72 which is connected to the third gas supply path 33. The first separation gas supply path 71 supplies a first separation gas of a hydrogen or inert gas to the third gas supply path 33. Further, the second separation gas supply path 72 supplies a second separation gas of a hydrogen or inert gas different from the first separation gas to the third gas supply path 33.

The molecular weight of the first compensation gas is smaller than that of the ammonia (NH₃), and the molecular weight of the second compensation gas is larger than that of the ammonia (NH₃). For example, the first separation gas is the hydrogen gas. Further, for example, the second separation gas is the nitrogen gas.

Then, the first separation gas supply path 71 includes a mass flow controller M5 (a fifth mass flow controller) which controls the flow amount of the first separation gas. The second separation gas supply path 72 includes a mass flow controller M6 (a sixth mass flow controller) which controls the flow amount of the second separation gas.

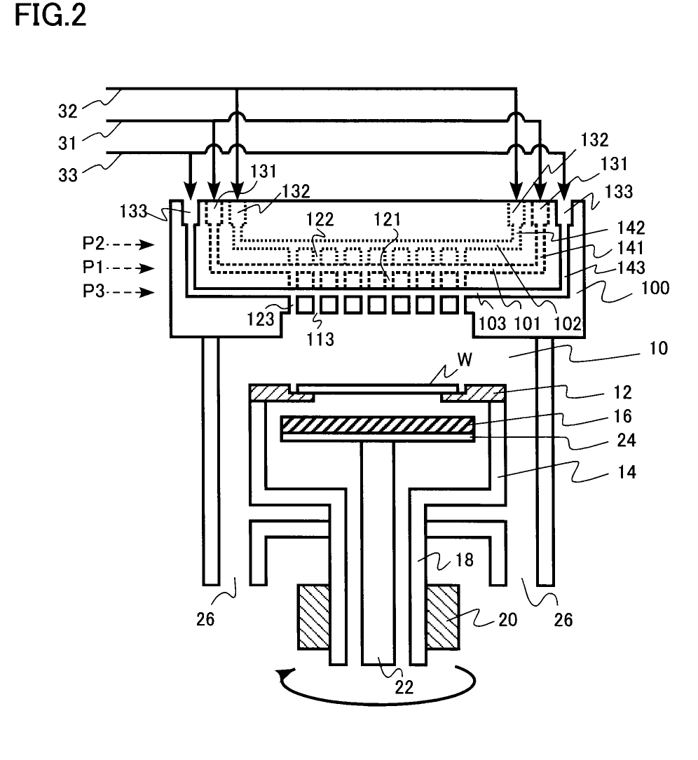

FIG. 2 is a schematic cross-sectional view illustrating a main part of the vapor phase growth apparatus of the embodiment.

As illustrated in FIG. 2, the epitaxial growth apparatus of the embodiment includes a reaction chamber 10 that is formed as, for example, stainless cylindrical hollow body. Then, the epitaxial growth apparatus includes a shower plate 100 that is disposed in the upper portion of the reaction chamber 10 and supplies a process gas into the reaction chamber 10.

Further, a support portion 12 is provided below the shower plate 100 inside the reaction chamber 10 so as to place a semiconductor wafer (a substrate) W thereon. The support portion 12 is, for example, an annular holder that has an opening formed at the center portion or a susceptor contacting the substantially entire rear surface of the semiconductor wafer W.

Further, a rotation unit 14 which rotates while disposing the support portion 12 on the upper surface thereof and a heater which serves as a heating unit 16 heating the wafer W placed on the support portion 12 are provided below the support portion 12. Here, a rotation shaft 18 of the rotation unit 14 is connected to a rotational driving mechanism 20 at the lower position thereof. Then, the semiconductor wafer W may be rotated at, for example, several tens of rpm to several thousands of rpm by the rotational driving mechanism 20 by using the center thereof as the rotation center.

It is desirable that the diameter of the cylindrical rotation unit 14 be substantially equal to the outer peripheral diameter of the support portion 12. Furthermore, the rotation shaft 18 is rotatably provided at the bottom portion of the reaction chamber 10 through a vacuum seal member.

Then, the heating unit 16 is provided while being fixed onto a support base 24 fixed to a support shaft 22 penetrating the inside of the rotation shaft 18. Electric power is supplied to the heating unit 16 by a current introduction terminal and an electrode (not illustrated). The support base 24 is provided with, for example, a push-up pin (not illustrated) that is used to attach or detach the semiconductor wafer W to or from the annular holder.

Further, the bottom portion of the reaction chamber 10 is provided with a gas discharge portion 26 that discharges a reaction product obtained by the reaction of a source gas on the surface of the semiconductor wafer W and a residual gas of the reaction chamber 10 to the outside of the reaction chamber 10. Furthermore, the gas discharge portion 26 is connected to a vacuum pump (not illustrated).

Then, the epitaxial growth apparatus of the embodiment includes the first gas supply path 31 which supplies the first process gas, the second gas supply path 32 which supplies the second process gas, and the third gas supply path 33 which supplies the third process gas.

Here, the separation gas as the third process gas is a gas which is ejected from third gas ejection holes 113 so as to separate the second process gas (here, ammonia) ejected from second gas ejection holes 112 and the first process gas (here, TMG) ejected from first gas ejection holes 111 from each other. For example, it is desirable to use a gas that has insufficient reactivity with the second process gas and the third process gas.

Furthermore, in the single wafer type epitaxial growth apparatus illustrated in FIG. 2, a wafer exit/entrance and a gate valve (not illustrated) through which the semiconductor wafer is inserted and extracted are provided at the side wall position of the reaction chamber 10. Then, the semiconductor wafer W may be carried by a handling arm between, for example, a load lock chamber (not illustrated) connected to the gate valve and the reaction chamber 10. Here, for example, the handling arm formed of synthetic quart may be inserted into the space between the shower plate 100 and the wafer support portion 12.

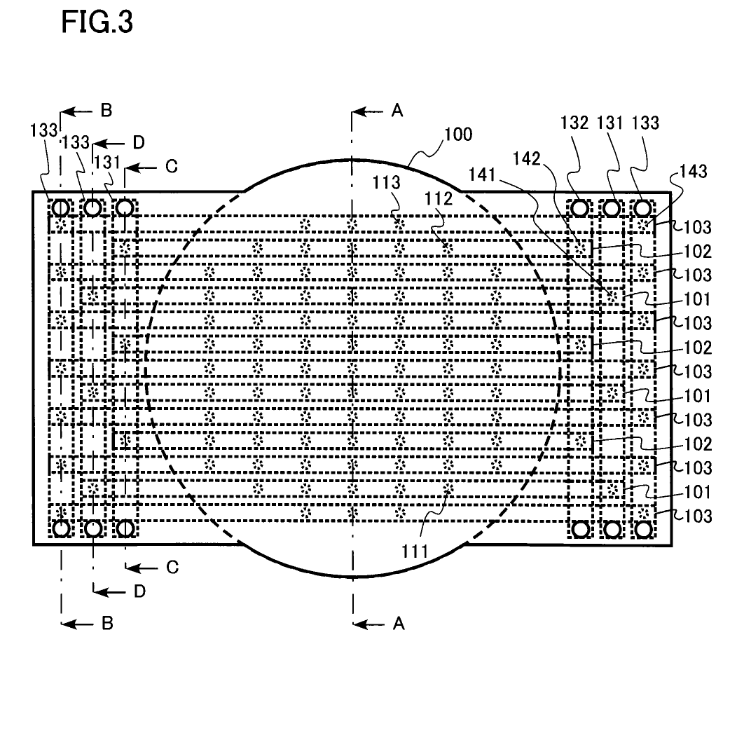

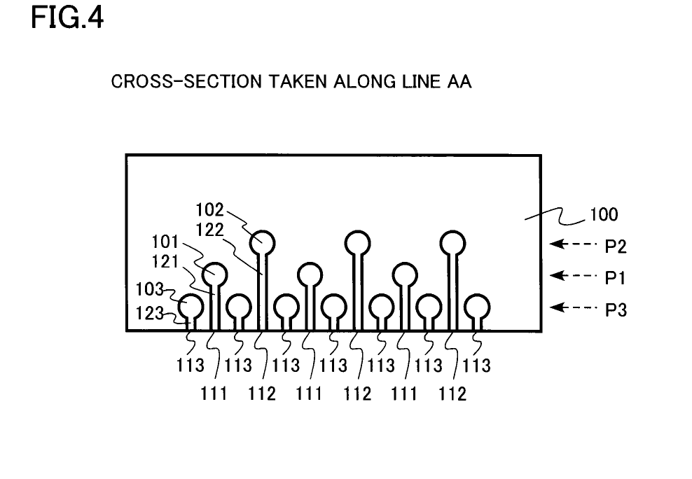

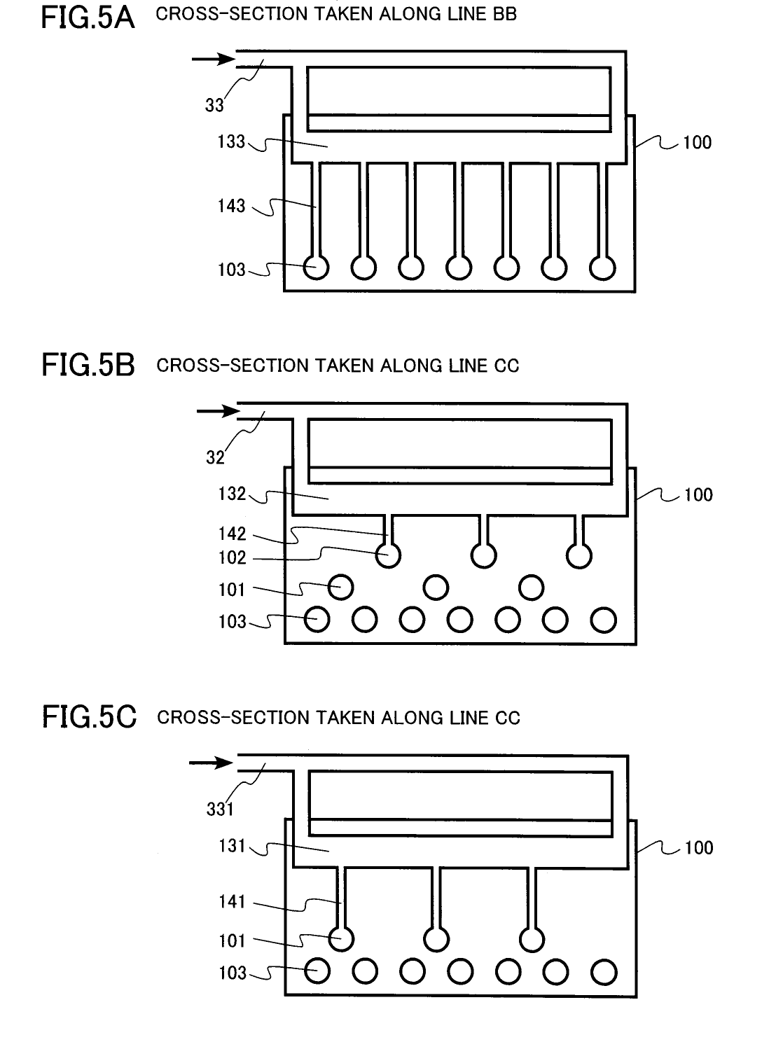

Hereinafter, the shower plate 100 of the embodiment will be described in detail. FIG. 3 is a schematic top view of the shower plate of the embodiment. FIG. 4 is a cross-sectional view taken along the line AA of FIG. 3, and FIGS. 5A to 5C are cross-sectional views taken along the lines BB, CC, and DD of FIG. 3.

The shower plate 100 has, for example, a plate shape with a predetermined thickness. The shower plate 100 is formed of, for example, a metal material such as stainless steel or aluminum alloy.

A plurality of first lateral gas passages 101, a plurality of second lateral gas passages 102, and a plurality of third lateral gas passages 103 are formed inside the shower plate 100. The plurality of first lateral gas passages 101 extend in parallel to each other within the first horizontal plane (P1). The plurality of second lateral gas passages 102 extend in parallel to each other while being disposed within the second horizontal plane (P2) above the first horizontal plane. The plurality of third lateral gas passages 103 are disposed within the third horizontal plane (P3) below the first horizontal plane so as to extend in parallel to each other.

Then, a plurality of first longitudinal gas passages 121 are provided which are connected to the first lateral gas passages 101 so as to extend in the longitudinal direction and include the first gas ejection holes 111 at the side of the reaction chamber 10. Further, a plurality of second longitudinal gas passages 122 are provided which are connected to the second lateral gas passages 102 so as to extend in the longitudinal direction and include the second gas ejection holes 112 at the side of the reaction chamber 10. In addition, a plurality of third longitudinal gas passages 123 are provided which are connected to the third lateral gas passages 103 so as to extend in the longitudinal direction and include third gas ejection holes 113 at the side of the reaction chamber 10.

The gas ejection holes 111, 112, and 113 have substantially the same hole diameters.

The second longitudinal gas passages 122 pass between the third lateral gas passages 103. The first longitudinal gas passages 121 pass between the third lateral gas passages 103.

The first lateral gas passages 101, the second lateral gas passages 102, and the third lateral gas passages 103 are lateral holes which are formed inside the plate-shaped shower plate 100 in the horizontal direction. Further, the first longitudinal gas passages 121, the second longitudinal gas passages 122, and the third longitudinal gas passages 123 are longitudinal holes which are formed inside the plate-shaped shower plate 100 in the gravity direction (the longitudinal direction or the vertical direction).

The inner diameters of the first, second, and third lateral gas passages 101, 102, and 103 are larger than the inner diameters of the first, second, and third longitudinal gas passages 121, 122, and 123 respectively corresponding thereto. In FIGS. 4 and 5A to 50, the first, second, and third lateral gas passages 101, 102, and 103 and the first, second, and third longitudinal gas passages 121, 122, and 123 have circular cross-sectional shapes, but the cross-sectional shapes are not limited to the circular shapes. For example, the cross-sectional shapes may be the other shapes such as oval, rectangular, and polygonal shapes.

The shower plate 100 includes a first manifold 131 that is connected to the first gas supply path 31 and is provided above the third horizontal plane (P3) and a first connection passage 141 that connects the first manifold 131 and each first lateral gas passage 101 at the end of the first lateral gas passage 101 and extends in the longitudinal direction.

The first manifold 131 has a function of distributing the first process gas supplied from the first gas supply path 31 to the plurality of first lateral gas passages 101 through the first connection passage 141. The first process gases distributed therefrom are introduced from the first gas ejection holes 111 of the plurality of first longitudinal gas passages 121 into the reaction chamber 10.

The first manifold 131 extends in a direction perpendicular to the first lateral gas passage 101, and has, for example, a hollow parallelepiped shape. In the embodiment, the first manifold 131 is provided in both ends of each first lateral gas passage 101, but may also be provided in at least one end thereof.

Further, the shower plate 100 includes a second manifold 132 that is connected to the second gas supply path 32 and is provided above the third horizontal plane (P3) and a second connection passage 142 that connects the second manifold 132 and each second lateral gas passage 102 at the end of the second lateral gas passage 102 and extends in the longitudinal direction.

The second manifold 132 has a function of distributing the second process gas supplied from the second gas supply path 32 to the plurality of second lateral gas passages 102 through the second connection passage 142. The second process gases distributed therefrom are introduced from the second gas ejection holes 112 of the plurality of second longitudinal gas passages 122 to the reaction chamber 10.

The second manifold 132 extends in a direction perpendicular to the second lateral gas passage 102, and has, for example, a hollow parallelepiped shape. In the embodiment, the second manifold 132 is provided in both ends of the second lateral gas passage 102, but may also be provided in at least one end thereof.

Further, the shower plate 100 includes a third manifold 133 that is connected to the third gas supply path 33 and is provided above the third horizontal plane (P3) and a third connection passage 143 that connects the third manifold 133 and each third lateral gas passage 103 at the end of the third lateral gas passage 103 and extends in the perpendicular direction.

The third manifold 133 has a function of distributing the third process gas supplied from the third gas supply path 33 to the plurality of third lateral gas passages 103 through the third connection passage 143. The third process gases distributed therefrom are introduced from the third gas ejection holes 113 of the plurality of third longitudinal gas passages 123 to the reaction chamber 10.

In the case where the semiconductor films of groups III to V are formed by MOCVD, for example, a gas which is obtained by diluting an organic metal gas of a group III by a hydrogen gas (H₂) as a carrier gas is used as the gas (the first process gas) including a group-III element. Meanwhile, ammonia (NH₃) is used as the source gas (the second process gas) of the group-V element.

In the case where the flow amount of the organic metal gas of the group III is smaller than the flow amount of the hydrogen gas as the carrier gas, the average molecular weight (the average density) of the gas (the first process gas) including the group-III element noticeably becomes smaller than the average molecular weight (the average density) of the source gas (the second process gas) of the group-V element. In this way, when the average molecular weight values are different from each other, a flow is easily disturbed at the boundary between the source gas (the first process gas) of the group-III element and the source gas (the second process gas) of the group-V element when both gases are supplied into the reaction chamber 10 at the same time.

For example, in the case where the first process gas of a group III is ejected from the first gas ejection holes 111 of the shower plate 100 into the reaction chamber 10 and the second process gas is ejected from the second gas ejection holes 112 into the reaction chamber 10, it is desirable that both gases reach onto the substrate while being uniformly mixed and rectified. However, as described above, when there is a large difference between the average molecular weight values, the dynamic pressure of the process gas having a large average molecular weight is larger than the dynamic pressure of the process gas having a small average molecular weight. For this reason, the static pressure of the process gas having a large average molecular weight decreases, and hence the process gas having a small average molecular weight is easily attracted toward the process gas having a large average molecular weight. For that reason, the flow at the boundary between both gases is easily disturbed, and hence a uniform rectified state may not be easily maintained.

In the vapor phase growth apparatus of in the embodiment, a mixed gas obtained by mixing the hydrogen gas (the first carrier gas) with the nitrogen gas (the second carrier gas) may be applied as the carrier gas. Accordingly, the average molecular weight (the average density) of the source gas (the first process gas) of the group-III element may approximate to that of the ammonia as the source gas (the second process gas) of the group-V element. Accordingly, it is possible to suppress the disturbance of the flow generated when the source gas (the first process gas) of the group-III element and the source gas (the second process gas) of the group-V element are simultaneously supplied into the reaction chamber 10. Accordingly, according to the vapor phase growth apparatus of the embodiment, it is possible to grow a film having an excellently uniform film thickness or film quality on the substrate.

Further, in the case where the semiconductor films of groups III to V are formed by MOCVD, for example, the hydrogen gas is supplied as the compensation gas with respect to the second gas supply path 32 during, for example, the hydrogen baking process before the source gas used for the film formation process is supplied to the reaction chamber. In this case, the average molecular weight of the hydrogen gas flowing at the early time noticeably becomes smaller than the average molecular weight of the ammonia gas. For this reason, when the hydrogen gas is switched to the ammonia gas, there is a concern that the distribution of the gas concentration or the flow of the ammonia gas inside the reaction chamber 10 may be degraded.

In the vapor phase growth apparatus of the embodiment, a mixed gas obtained by mixing the hydrogen gas (the first compensation gas) with the nitrogen gas (the second compensation gas) may be applied as the compensation gas of the ammonia gas. Accordingly, the average molecular weight of the compensation gas supplied to the reaction chamber 10 before the semiconductor film is formed may approximate to the average molecular weight of the second process gas including ammonia gas used for the film formation process. Accordingly, it is possible to suppress the disturbance of the flow of the ammonia gas or the environment change of the reaction chamber 10 when the compensation gas is switched to the ammonia gas. Accordingly, according to the vapor phase growth apparatus of the embodiment, it is possible to grow a film having an excellently uniform film thickness or film quality on the substrate.

Further, in the case where a gas, for example, the hydrogen gas having an average molecular weight noticeably smaller than the ammonia gas is used as the separation gas when the source gas (the first process gas) of the group-III element and the source gas (the second process gas) of the group-V element are separated from each other inside the reaction chamber 10, there is a concern that the flow at the boundary between the ammonia gas and the separation gas may be disturbed due to the difference in the average molecular weight.

In the vapor phase growth apparatus of the embodiment, a mixed gas obtained by mixing the hydrogen gas (the first separation gas) with the nitrogen gas (the second separation gas) may be applied as the separation gas. Accordingly, the average molecular weight of the separation gas supplied to the reaction chamber 10 may approximate to the average molecular weight of the first process gas or the second process gas including ammonia gas. Accordingly, it is possible to suppress the disturbance of the flow generated at the boundary between the separation gas and the first or second process gas ejected into the reaction chamber 10. Accordingly, according to the vapor phase growth apparatus of the embodiment, it is possible to grow a film having an excellently uniform film thickness or film quality on the substrate.

Further, it is desirable that the flow amount of the process gas ejected into the reaction chamber 10 from the gas ejection hole generally provided as the process gas supply port in the shower plate be uniform in each gas ejection space from the viewpoint of ensuring the uniformity in the film formation quality. According to the shower plate 100 of the embodiment, the process gas is distributed to the plurality of lateral gas passages and then is distributed to the longitudinal gas passages so as to be ejected from the gas ejection holes. With this configuration, it is possible to improve the uniformity of the flow amount of the process gas ejected from the gas ejection holes by a simple structure.

Further, it is desirable that the arrangement density of the gas ejection holes disposed from the viewpoint of the uniform formation of the film be set as large as possible. More than anything else, in the configuration provided with the plurality of lateral gas passages arranged in parallel to each other as in the embodiment, when the density of the gas ejection holes is increased, a trade-off occurs between the arrangement density of the gas ejection hole and the inner diameter of the lateral gas passage.

For this reason, the fluid resistance of the lateral gas passage increases with a decrease in the inner diameter of the lateral gas passage, and the flow amount distribution of the flow amount of the process gas ejected from the gas ejection hole with respect to the extension direction of the lateral gas passage increases. As a result, there is a concern that the uniformity of the flow amount of the process gas ejected from the respective gas ejection holes may be degraded.

According to the vapor phase growth apparatus of the embodiment, a layered structure is formed in which the first lateral gas passage 101, the second lateral gas passage 102, and the third lateral gas passage 103 are provided in different horizontal planes. With this structure, the margin with respect to an increase in the inner diameter of the lateral gas passage is improved. Accordingly, it is possible to suppress an increase in the flow amount distribution caused by the inner diameter of the lateral gas passage while ensuring the density of the gas ejection holes. As a result, it is possible to improve the uniformity of the formation of the film by equalizing the flow amount distribution of the process gas ejected into the reaction chamber 10.

The vapor phase growth method of the embodiment will be described by exemplifying the case where the epitaxial growth of GaN is performed by the single wafer type epitaxial growth apparatus.

The carrier gas is supplied to the reaction chamber 10, the vacuum pump (not illustrated) is operated so as to discharge the gas inside the reaction chamber 10 from the gas discharge portion 26, and the semiconductor wafer W is placed on the support portion 12 inside the reaction chamber 10 while the reaction chamber 10 is controlled at a predetermined pressure. Here, the gate valve (not illustrated) of the wafer exit/entrance of the reaction chamber 10 is opened, and the semiconductor wafer W of the load lock chamber is carried into the reaction chamber 10 by the handling arm. Then, the semiconductor wafer W is placed on the support portion 12 through, for example, the push-up pin (not illustrated), the handling arm is returned to the load lock chamber, and the gate valve is closed.

Here, the semiconductor wafer W placed on the support portion 12 is pre-heated to a predetermined temperature by the heating unit 16.

Further, the heating output of the heating unit 16 is increased so that the temperature of the semiconductor wafer W increases to a predetermined temperature, for example, a baking temperature of about 1150° C.

Then, the evacuation is performed by the vacuum pump, and the baking process is performed before the film formation process while the rotation unit 14 is rotated at a necessary speed. Due to the baking process, for example, the natural oxide film on the semiconductor wafer W is removed.

During the baking process, for example, the hydrogen gas is supplied to the reaction chamber 10 through the first gas supply path 31. Further, for example, the hydrogen gas is supplied to the reaction chamber 10 through the second gas supply path 32. Further, for example, the hydrogen gas is supplied to the reaction chamber 10 through the third gas supply path 33. After the natural oxide film is removed, for example, the mixed gas obtained by mixing the hydrogen gas with the nitrogen gas is supplied to the reaction chamber 10 through the first gas supply path 31. Further, for example, the mixed gas obtained by mixing the hydrogen gas with the nitrogen gas is supplied to the reaction chamber 10 through the second gas supply path 32. Further, for example, the mixed gas obtained by mixing the hydrogen gas with the nitrogen gas is supplied to the reaction chamber 10 through the third gas supply path 33.

Then, for example, the compensation gas as the mixed gas (the second mixed gas) obtained by mixing the first compensation gas as the hydrogen gas with the second compensation gas as the nitrogen gas is supplied to the reaction chamber. The first compensation gas is supplied from the first compensation gas supply path 61 to the second gas supply path 32 while the flow amount thereof is controlled by the mass flow controller M3 (the third mass flow controller). The second compensation gas is supplied from the second compensation gas supply path 62 to the second gas supply path 32 while the flow amount thereof is controlled by the mass flow controller M4 (the fourth mass flow controller).

From the viewpoint of suppressing the generation of the turbulent flow or the environment change inside the reaction chamber 10 when the compensation gas is switched to the ammonia gas, it is desirable that the average molecular weight (the density) of the compensation gas ejected from the second gas ejection holes 112 into the reaction chamber 10 approximate to the average molecular weight of the ammonia ejected from the second gas ejection holes 112 into the reaction chamber 10 during the film formation process.

The average molecular weight of the compensation gas is desirably in the range of 80% to 120% of the average molecular weight of the second process gas including ammonia, and is more desirably in the range of 90% to 110%. It is further desirable that the average molecular weight of the compensation gas be substantially equal to the average molecular weight of the second process gas.

The average molecular weight of the compensation gas may be controlled by adjusting the flow amount of the first compensation gas and the second compensation gas using the mass flow controller M3 (the third mass flow controller) and the mass flow controller M4 (the fourth mass flow controller).

Next, the heating output of the heating unit 16 is decreased so that the temperature of the semiconductor wafer W falls to the epitaxial growth temperature, for example, 1100° C.

Then, predetermined first to third process gases are ejected from the first to third gas ejection holes 111, 112, and 113. The first process gas is ejected from the first gas ejection holes 111 into the reaction chamber 10 while passing through the first manifold 131, the first connection passage 141, the first lateral gas passage 101, and the first longitudinal gas passage 121 from the first gas supply path 31. Further, the second process gas is ejected from the second gas ejection holes 112 into the reaction chamber 10 while passing through the second manifold 132, the second connection passage 142, the second lateral gas passage 102, and the second longitudinal gas passage 122 from the second gas supply path 32. Further, the third process gas (the third mixed gas or the separation gas) is ejected from the third gas ejection holes 113 into the reaction chamber 10 while passing through the third manifold 133, the third connection passage 143, the third lateral gas passage 103, and the third longitudinal gas passage 123 from the third gas supply path 33. The third process gas is supplied into the reaction chamber 10 along with the first and second process gases.

The compensation gas ejected from the second gas ejection holes 112 is switched to the second process gas including ammonia. Since control is performed so that the average molecular weight values approximate to each other, the environment change or the turbulent flow generated inside the reaction chamber 10 due to the switching is suppressed. Accordingly, it is possible to grow a film having an excellently uniform film thickness or film quality on the substrate.

Further, the first process gas is a gas in which trimethylgallium (TMG) is diluted by the mixed gas (the first mixed gas) obtained by mixing the hydrogen gas as the first carrier gas with the nitrogen gas as the second carrier gas. The first carrier gas is supplied from the first carrier gas supply path 51 to the first gas supply path 31 while the flow amount thereof is controlled by the mass flow controller M1 (the first mass flow controller). The second carrier gas is supplied from the second carrier gas supply path 52 to the first gas supply path 31 while the flow amount thereof is controlled by the mass flow controller M2 (the second mass flow controller).

In order to suppress the disturbance of the flow generated between the first process gas and the second process gas when both gases are ejected into the reaction chamber 10, it is desirable that the average molecular weight (the density) of the first process gas ejected from the first gas ejection holes 111 into the reaction chamber 10 approximate to the average molecular weight of the ammonia ejected from the second gas ejection holes 112 into the reaction chamber 10.

In order to prevent the disturbance of the flow between the first process gas and the second process gas, the average molecular weight of the first process gas is desirably in the range of 80% to 120% of the average molecular weight of the second process gas including ammonia, and is more desirably in the range of 90% to 110% thereof. It is further desirable that the average molecular weight of the first process gas is substantially equal to the average molecular weight of the second process gas.

The average molecular weight of the first process gas may be controlled by adjusting the flow amount of the first carrier gas and the second carrier gas using the mass flow controller M1 (the first mass flow controller) and the mass flow controller M2 (the second mass flow controller).

Since control is performed so that the average molecular weight values of the first process gas and the second process gas approximate to each other, the disturbance of the flow generated at the boundary between the first process gas and the second process gas is suppressed. Accordingly, it is possible to grow a film having an excellently uniform film thickness or film quality on the substrate.

Further, the separation gas (the third mixed gas or the third process gas) from the first gas ejection holes 111 which eject the first process gas into the reaction chamber 10 and the third gas ejection holes 113 provided between the second gas ejection holes 112 ejecting the second process gas into the reaction chamber 10 is the mixed gas (the third mixed gas) obtained by mixing the hydrogen gas as the first separation gas with the nitrogen gas as the second separation gas.

In order to suppress the disturbance of the flow between the separation gas and the first process gas or the second process gas when both gases are ejected into the reaction chamber 10, it is desirable that the average molecular weight (the density) of the separation gas ejected from the third gas ejection holes 113 approximate to the average molecular weight (the density) of the first process gas ejected from the first gas ejection holes 111 into the reaction chamber 10 or the average molecular weight of the second process gas including ammonia ejected from the second gas ejection holes 112 into the reaction chamber 10.

In order to suppress the disturbance of the flow between the separation gas and the first process gas or the second process gas, the average molecular weight of the separation gas is desirably in the range of 80% to 120% of the average molecular weight of the first process gas or the second process gas including ammonia, and is more desirably in the range of 90% to 110% thereof. It is further desirable that the average molecular weight of the separation gas be substantially equal to the average molecular weight of the first process gas or the average molecular weight of the second process gas.

Furthermore, when there is a difference between the average molecular weight of the first process gas and the average molecular weight of the second process gas, it is desirable that the average molecular weight of the separation gas be equal to or larger than the average molecular weight of the first process gas and equal to or smaller than the average molecular weight of the second process gas from the viewpoint of suppress the disturbance of the flow between both gases.

The average molecular weight of the first process gas may be controlled by adjusting the flow amount of the first carrier gas and the second carrier gas using the mass flow controller M1 (the first mass flow controller) and the mass flow controller M2 (the second mass flow controller).

Since control is performed so that the average molecular weight of the separation gas approximate to the average molecular weight of the first process gas or the second process gas, the disturbance of the flow generated at the boundary between the separation gas and the first process gas or the second process gas is suppressed. Accordingly, it is possible to grow a film having an excellently uniform film thickness or film quality on the substrate.

The first to third process gases ejected from the first to third gas ejection holes 111, 112, and 113 are appropriately mixed with one another, and are supplied onto the semiconductor wafer W in a rectified state. At this time, the semiconductor wafer W is heated to 1000 to 1200° C. while rotating at, for example, 800 to 1200 rpm. Accordingly, for example, a single-crystal film of GaN (gallium nitride) is formed on the surface of the semiconductor wafer W by the epitaxial growth. Since an appropriate rotation number is set, the uniformity of the film thickness within the surface of the semiconductor wafer W may be improved. Further, in the case where a film that easily produce powder in a vapor phase state is formed as in the case of AlN (aluminide), the boundary layer formed on the semiconductor wafer W is thinned when the rotation number is increased to 2000 to 3000 rpm or so, and hence the production of powder may be reduced. In the case where the growth of InGaN (indium gallium nitride) is performed, a film is formed by increasing the temperature of the semiconductor wafer W to 700 to 900° C. or so.

Then, when the epitaxial growth ends, the source gas of a group III flows to the first gas discharge path 54 while the flowing thereof into the first gas supply path 31 is interrupted, and then the growth of the single-crystal film ends. After the temperature of the semiconductor wafer W decreases to a predetermined temperature in a manner such that the heating output of the heating unit 16 is decreased so as to decrease the temperature of the semiconductor wafer W, the supply of the ammonia from the second gas supply path 32 into the reaction chamber 10 is stopped, and the compensation gas is supplied to the second gas supply path 32.

Here, for example, the rotation of the rotation unit 14 is stopped, and the heating output of the heating unit 16 is returned to the first state so as to decrease the temperature to the pre-heating temperature while the semiconductor wafer W having the single-crystal film formed thereon is placed on the support portion 12.

Next, after the temperature of the semiconductor wafer W is stabilized at a predetermined temperature, the semiconductor wafer W is attached to or detached from the support portion 12 by, for example, the push-up pin. Then, the gate valve is opened again, the handling arm is inserted between the shower plate 100 and the support portion 12, and the semiconductor wafer W is placed thereon. Then, the handling arm that loads the semiconductor wafer W thereon is returned to the load lock chamber.

As described above, each film formation process for the semiconductor wafer W ends. In succession, for example, the film formation process on the other semiconductor wafer W may be performed according to the same process sequence as the above-described one.

In the vapor phase growth method of the embodiment, the flow of the process gas may be uniformly stabilized, and hence a film having an excellently uniform film thickness or film quality may be formed on the substrate.

### Second Embodiment

A vapor phase growth apparatus of the embodiment includes: a reaction chamber; a first gas supply path configured to supply a first process gas including organic metal and a carrier gas into the reaction chamber; a second gas supply path configured to supply a second process gas including ammonia into the reaction chamber; a first compensation gas supply path configured to supply a first compensation gas of a hydrogen or inert gas to the second gas supply path while being connected to the second gas supply path and including a third mass flow controller; and a second compensation gas supply path configured to supply a second compensation gas of a hydrogen or inert gas different from the first compensation gas to the second gas supply path while being connected to the second gas supply path and including a fourth mass flow controller.

The vapor phase growth apparatus of the embodiment is the same as that of the first embodiment except that a mechanism for supplying a mixed gas to the first gas supply path and the third gas supply path is removed from the apparatus of the first embodiment. Accordingly, the same description as that of the first embodiment will not be repeated.

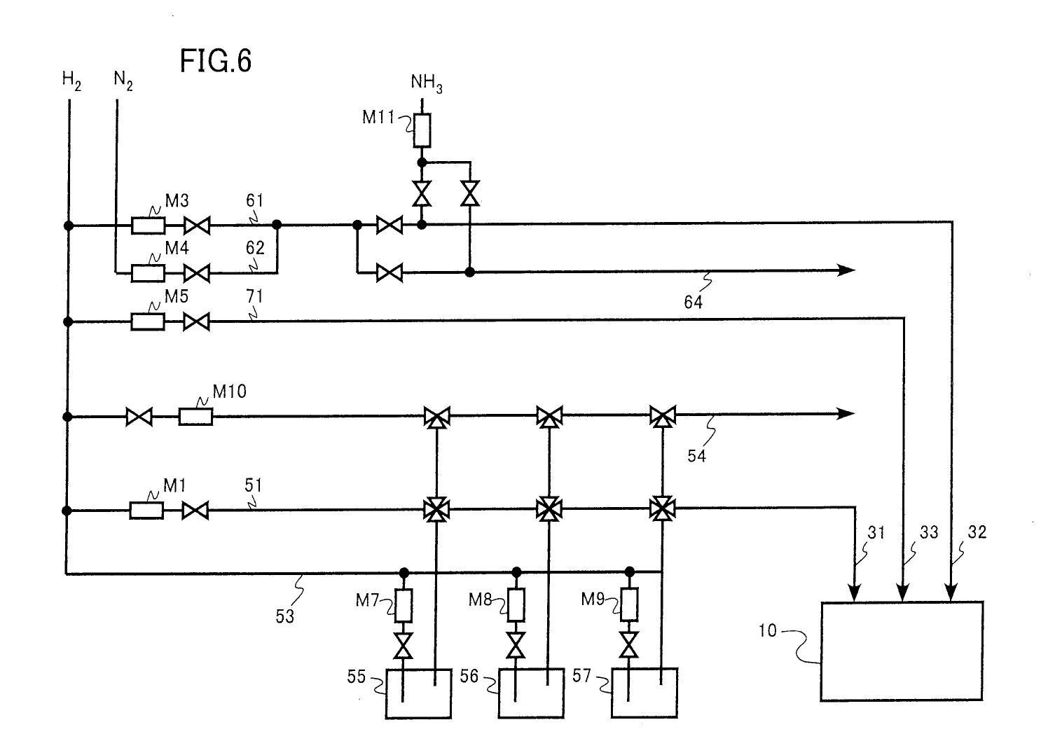

FIG. 6 is a configuration diagram of the vapor phase growth apparatus of the embodiment.

The vapor phase growth apparatus of the embodiment includes a first compensation gas supply path 61 which is connected to the second gas supply path 32 and supplies a first compensation gas of a hydrogen or inert gas to the second gas supply path 32. Further, a second compensation gas supply path 62 is provided which is connected to the second gas supply path 32 and supplies a second compensation gas of a hydrogen or inert gas different from the first compensation gas to the second gas supply path 32.

Further, a vapor phase growth method of the embodiment includes: carrying a substrate into a reaction chamber; heating the substrate; and forming a semiconductor film on a substrate surface by supplying a second mixed gas obtained by mixing a first compensation gas of a hydrogen or inert gas with a second compensation gas of a hydrogen or inert gas different from the first compensation gas into the reaction chamber and supplying a first process gas including organic metal and a carrier gas of a hydrogen or inert gas and a second process gas including ammonia into the reaction chamber. The second mixed gas and the second process gas are ejected from the same gas ejection hole into the reaction chamber.

The molecular weight of the first compensation gas is smaller than that of the ammonia (NH₃), and the molecular weight of the second compensation gas is larger than that of the ammonia (NH₃). For example, the first compensation gas is the hydrogen gas. Further, for example, the second compensation gas is the nitrogen gas.

Then, the first compensation gas supply path 61 includes a mass flow controller M3 (a third mass flow controller) which controls the flow amount of the first compensation gas. Further, the second compensation gas supply path 62 includes a mass flow controller M4 (a fourth mass flow controller) which controls the flow amount of the second compensation gas.

In the vapor phase growth apparatus of the embodiment, a mixed gas obtained by mixing the hydrogen gas (the first compensation gas) with the nitrogen gas (the second compensation gas) may be applied as the compensation gas of the ammonia gas. Accordingly, the average molecular weight of the compensation gas supplied to the reaction chamber 10 before the semiconductor film formation process and the average molecular weight of the ammonia gas (the second process gas) during the film formation process may be evenly adjusted. Accordingly, it is possible to suppress the disturbance of the flow of the ammonia gas or the environment change of the reaction chamber 10 when the compensation gas is switched to the ammonia gas. Accordingly, according to the vapor phase growth apparatus of the embodiment, it is possible to grow a film having an excellently uniform film thickness or film quality on the substrate.

Further, according to the vapor phase growth method of the embodiment, the compensation gas (the second mixed gas) ejected from the second gas ejection holes 112 is switched to the second process gas including ammonia. Since control is performed so that the average molecular weight values thereof approximate to each other, the disturbance of the flow or the environment change inside the reaction chamber 10 due to the switching may be suppressed. Accordingly, it is possible to grow a film having an excellently uniform film thickness or film quality on the substrate.

### Third Embodiment

A vapor phase growth apparatus of the embodiment includes: a reaction chamber; a first gas supply path configured to supply a first process gas including organic metal and a carrier gas into the reaction chamber; a second gas supply path configured to supply a second process gas including ammonia into the reaction chamber; a third gas supply path configured to supply a third process gas into the reaction chamber; a first separation gas supply path configured to supply a first separation gas of a hydrogen or inert gas to the third gas supply path while being connected to the third gas supply path and including a fifth mass flow controller; and a second separation gas supply path configured to supply a second separation gas of a hydrogen or inert gas different from the first separation gas to the third gas supply path while being connected to the third gas supply path and including a sixth mass flow controller.

Further, a vapor phase growth method of the embodiment includes: carrying a substrate into a reaction chamber; heating the substrate; and forming a semiconductor film on a substrate surface by supplying a first process gas including organic metal and a carrier gas of a hydrogen or inert gas, a second process gas including ammonia, and a third mixed gas (a separation gas or a third process gas) obtained by mixing a first separation gas of a hydrogen or inert gas and a second separation gas of a hydrogen or inert gas different from the first separation gas into the reaction chamber.

The vapor phase growth apparatus of the embodiment is different from that of the first embodiment except that a mechanism for supplying a mixed gas to the first gas supply path and the second gas supply path is removed from the first embodiment. Accordingly, the same description as that of the first embodiment will not be repeated.

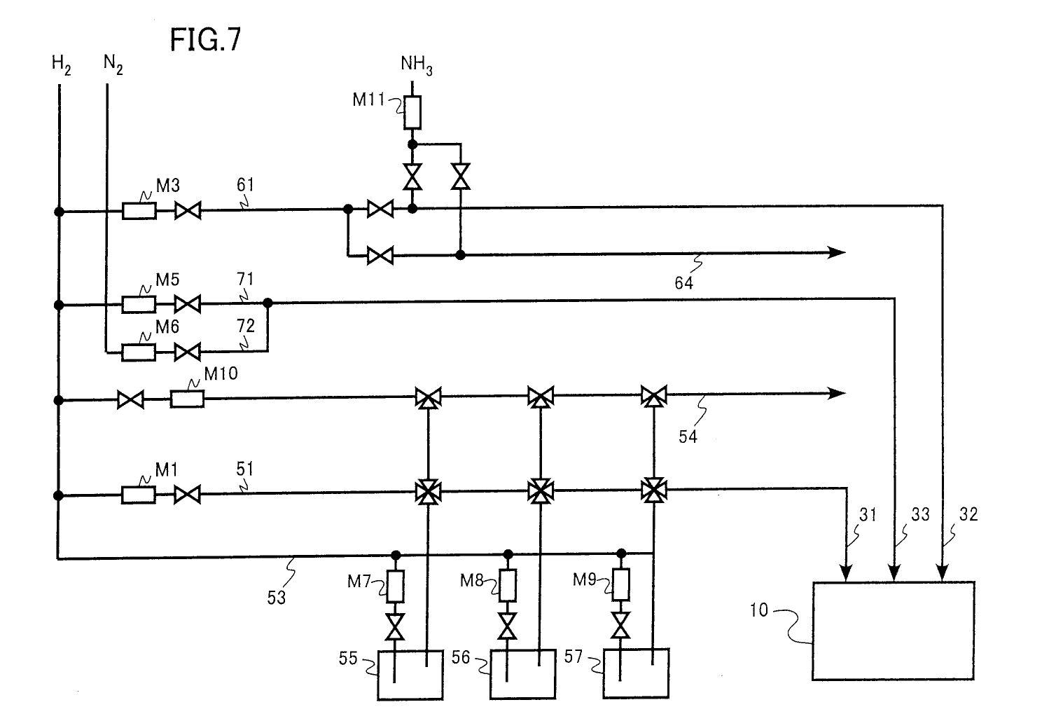

FIG. 7 is a configuration diagram of the vapor phase growth apparatus of the embodiment.

The vapor phase growth apparatus of the embodiment includes a first separation gas supply path 71 and a second separation gas supply path 72 connected to the third gas supply path 33. The first separation gas supply path 71 supplies a first separation gas of a hydrogen or inert gas to the third gas supply path 33. Further, the second separation gas supply path 72 supplies a second separation gas of a hydrogen or inert gas different from the first separation gas to the third gas supply path 33.

The molecular weight of the first compensation gas is smaller than that of the ammonia (NH₃), and the molecular weight of the second compensation gas is larger than that of the ammonia (NH₃). For example, the first separation gas is the hydrogen gas. Further, for example, the second separation gas is the nitrogen gas.

Then, the first separation gas supply path 71 includes a mass flow controller M5 (a fifth mass flow controller) which controls the flow amount of the first separation gas. The second separation gas supply path 72 includes a mass flow controller M6 (a sixth mass flow controller) which controls the flow amount of the second separation gas.

In the vapor phase growth apparatus of the embodiment, a mixed gas obtained by mixing the hydrogen gas (the first separation gas) with the nitrogen gas (the second separation gas) may be applied as the separation gas. Accordingly, the average molecular weight of the separation gas supplied to the reaction chamber 10 may be evenly adjusted to the average molecular weight of the first process gas or the second process gas including the ammonia gas. Accordingly, it is possible to suppress the disturbance of the gas generated at the boundary between the separation gas and the first or second process gas ejected into the reaction chamber 10. Accordingly, according to the vapor phase growth apparatus of the embodiment, it is possible to grow a film having an excellently uniform film thickness or film quality on the substrate.

Further, according to the vapor phase growth method of the embodiment, control is performed so that the average molecular weight of the separation gas approximates to the average molecular weight of the first process gas or the second process gas. For this reason, the turbulent flow generated at the boundary between the separation gas and the first process gas or the second process gas is suppressed. Accordingly, it is possible to grow a film having an excellently uniform film thickness or film quality on the substrate.

Furthermore, from the viewpoint of improving the performance of separating the first process gas and the second process gas from each other, it is desirable that the third mixed gas be ejected from the first gas ejection holes 111 which eject the first process gas from the reaction chamber 10 and the third gas ejection holes 113 which are provided between the second gas ejection holes 112 ejecting the second process gas to the reaction chamber 10.

As described above, the embodiments have been described with reference to the specific examples. However, the above-described embodiments are merely examples, and do not limit the present disclosure. Further, the components of the embodiments may be appropriately combined with each other.

For example, in the embodiments, a case has been described in which three kinds of passages such as the lateral gas passage are provided. However, four kinds or more of passages such as the lateral gas passage may be provided or two kinds of passages may be provided.

Further, for example in the embodiments, a case has been described in which the single-crystal film of GaN (gallium nitride) is formed, but the disclosure may be also applied to, for example, the case of forming single-crystal films of the other nitride-based semiconductors of groups III to V such as AlN (aluminum nitride), AlGaN (aluminum gallium nitride), and InGaN (indium gallium nitride).

Further, the hydrogen gas (H₂) and the nitrogen gas (N₂) have been exemplified as the combination of the gases used in the mixed gas. However, for example, the other combinations selected from the hydrogen gas or the inert gas such as the combination of the hydrogen gas (H₂) and the argon gas (Ar) and the combination of the helium gas (He) and the nitrogen gas (N₂) may be applied.

Further, in the embodiments, an example of the vertical single wafer type epitaxial apparatus that forms a film on each wafer has been described, but the vapor phase growth apparatus is not limited to the single wafer type epitaxial apparatus. For example, the embodiments may be also applied to a horizontal epitaxial apparatus or a planetary CVD apparatus that simultaneously forms a film on a plurality of wafers that revolve in a spinning state.

For example, a configuration is effective in which the sub-flow gas of the horizontal epitaxial apparatus is used as the third process gas (the third mixed gas) of the third embodiment.

In the embodiments, the apparatus configuration or the manufacturing method which is not directly necessary for the description of the invention is not described, but the apparatus configuration or the manufacturing method which needs to be used may be appropriately selected and used. In addition, all vapor phase growth apparatuss and vapor phase growth methods that include the components of the invention and may be appropriately modified in design by the person skilled in the art are included in the scope of the invention. The scope of the invention is defined by the claims and the scope of the equivalent thereof.

What is claimed is:

1. A vapor phase growth apparatus comprising:
a reaction chamber;
a first gas supply path connected to the reaction chamber, the first gas supply path configured to supply a first process gas including organic metal and a carrier gas into the reaction chamber;
a second gas supply path connected to the reaction chamber, the second gas supply path configured to supply a second process gas including ammonia into the reaction chamber;
a first carrier gas supply path connected to the first gas supply path, the first carrier gas supply path having a first mass flow controller, the first carrier gas supply path configured to supply a first carrier gas of a hydrogen or inert gas into the first gas supply path; and
a second carrier gas supply path connected to the first gas supply path, the second carrier gas supply path having a second mass flow controller, the second carrier gas supply path configured to supply a second carrier gas of a hydrogen or inert gas different from the first carrier gas into the first gas supply path.

2. The vapor phase growth apparatus according to claim 1, further comprising:
a first compensation gas supply path connected to the second gas supply path, the first compensation gas supply path having a third mass flow controller, the first compensation gas supply path configured to supply a first compensation gas of a hydrogen or inert gas into the second gas supply path; and
a second compensation gas supply path connected to the second gas supply path, the second compensation gas supply path having a fourth mass flow controller, the second compensation gas supply path configured to supply a second compensation gas of a hydrogen or inert gas different from the first compensation gas into the second gas supply path.

3. The vapor phase growth apparatus according to claim 1, further comprising:
a third gas supply path connected to the reaction chamber, the third gas supply path configured to supply a third process gas into the reaction chamber;
a first separation gas supply path connected to the third gas supply path, the first separation gas supply path having a fifth mass flow controller, the first separation gas supply path configured to supply a first separation gas of a hydrogen or inert gas into the third gas supply path; and
a second separation gas supply path connected to the third gas supply path, the second separation gas supply path having a sixth mass flow controller, the second separation gas supply path configured to supply a second separation gas of a hydrogen or inert gas different from the first separation gas into the third gas supply path.

4. The vapor phase growth apparatus according to claim 1,
wherein the first carrier gas is a hydrogen gas, and the second carrier gas is a nitrogen gas.

5. The vapor phase growth apparatus according to claim 2,
wherein the first compensation gas is a hydrogen gas, and the second compensation gas is a nitrogen gas.

6. The vapor phase growth apparatus according to claim 3,
wherein the first separation gas is a hydrogen gas, and the second separation gas is a nitrogen gas.

7. A vapor phase growth method comprising:
carrying in a substrate into a reaction chamber;
heating the substrate; and
forming a semiconductor film on a substrate surface by supplying a first process gas including organic metal and a first mixed gas obtained by mixing a first carrier gas of a hydrogen or inert gas with a second carrier gas of a hydrogen or inert gas different from the first carrier gas and a second process gas including ammonia into the reaction chamber.

8. The vapor phase growth method according to claim 7,
wherein a second mixed gas obtained by mixing a first compensation gas of a hydrogen or inert gas with a second compensation gas of a hydrogen or inert gas different from the first compensation gas is supplied into the reaction chamber before the supply of the second process gas into the reaction chamber, and
wherein a semiconductor film is formed on the substrate surface by switching supply gas from the second mixed gas to the second process gas.

9. The vapor phase growth method according to claim 8,
wherein a third mixed gas obtained by mixing a first separation gas of a hydrogen or inert gas with a second separation gas of a hydrogen or inert gas different from the first separation gas is supplied into the reaction chamber along with the first process gas and the second process gas when the first process gas and the second process gas are supplied into the reaction chamber.

10. The vapor phase growth method according to claim 9,
wherein the third mixed gas is ejected from a third gas ejection hole provided between a first gas ejection hole ejecting the first process gas into the reaction chamber and a second gas ejection hole ejecting the second process gas into the reaction chamber.

11. The vapor phase growth method according to claim 7,
wherein the first carrier gas is a hydrogen gas, and the second carrier gas is a nitrogen gas.

12. The vapor phase growth method according to claim 8,
wherein the first compensation gas is a hydrogen gas, and the second compensation gas is a nitrogen gas.

13. The vapor phase growth method according to claim 9,
wherein the first separation gas is a hydrogen gas, and the second separation gas is a nitrogen gas.
